(19) United States
(12) Patent Application Publication
(10) Pub. No.: US 2012/0081148 A1
(43) Pub. Date: Apr. 5, 2012

(54) PROGRAMMABLE LOGIC DEVICE

(75) Inventor: PAUL BONWICK, Bristol (GB)

(73) Assignee: PANASONIC CORPORATION, Osaka (JP)

(21) Appl. No.: 12/895,370

(22) Filed: Sep. 30, 2010

(51) Int. Cl. H03K 19/177

(52) U.S. Cl. 326/40

(57) ABSTRACT

A programmable logic device includes a plurality of repeating units, each of which includes interconnecting lines, a logic block comprising logic circuits, and a configuration memory block including a plurality of configuration memory circuits. One of the plurality of repeating units includes: a selection device coupled to output data of the plurality of configuration memory circuits and a shift chain segment input; and a flip flop receiving output of the selection device to output a shift chain segment output.

### TECHNICAL FIELD

The technical field relates to programmable logic devices (PLDs), and more particularly to a test system for use in programmable logic devices such as field programmable logic arrays (FPGAs), and application-specific integrated circuits (ASICs).

### BACKGROUND

It is desirous to provide a test strategy for PLDs, especially for programmable resources provided in PLDs.

FIG. 9 shows a conventional test strategy described in a U.S. Pat. No. 5,651,013, hereinafter Patent Reference 1. Shown therein is a logic cell 20 having cell input multiplexing 64 and output multiplexing 66 which effect the connections between the logic cell 20 and the programmable interconnect network 22. Also depicted in cell 20 is cell combinational logic 68 which performs logic functions on logic cell input signals and which produces at least one resultant logic signal 62. Signal 62 is applied to a storage circuit 50. Storage circuit 50, which conventionally is a master/slave delayed flip-flop (D-FF) having an output 60, is converted into a shift register stage having a scan input 52, a scan output 58 and inputs for A, B and C scan clock signals from a scan clock distribution network 54. Multiple such storage circuits can be provided in a single logic cell. Each storage circuit 50 of each logic cell 20 of a programmable array can be converted and connected into a scan chain using its respective scan input and scan output lines.
Patent Reference 1: U.S. Pat. No. 5,651,013

### SUMMARY

With the test system described in the Patent Reference 1, D-FFs in a logic cell can be converted and connected into a scan chain. Therefore, D-FFs can be tested by using conventional automated test pattern generator (ATPG) methodology. However, in conventional art, latch circuits, which are smaller than D-FFs, are usually used as configuration memories in order to conserve area of chip on which the PLD is fabricated. Latch circuits such as SRAM cannot be tested by using conventional ATPG methodology. Therefore, a technique to make it possible to test the latch circuits of configuration memories by using conventional ATPG methodology is desired.

To achieve the object, as well as other concerns, in a programmable logic device including a plurality of repeating units, each of which includes interconnecting lines, a logic block comprising logic circuits, and a configuration memory block including a plurality of configuration memory circuits, one of the plurality of repeating units includes: a selection device coupled to output data of the plurality of configuration memory circuits and a shift chain segment input; and a flip flop receiving output of the selection device to output a shift chain segment output.

The plurality of configuration memory circuits are latch circuits, preferably. Another of the plurality of repeating units includes another flip flop for providing the shift chain segment input, preferably.

In the programmable logic device, the one of the plurality of repeating units further includes: a plurality of first switching circuits coupled to the output data of the plurality of configuration memory circuits respectively and the selection device; and a plurality of second switching circuits coupled to input data of the plurality of configuration memory circuits respectively and the shift chain segment input/Data is read from one of the plurality of configuration memory circuits by controlling the respective first switching circuit and the selection device. Data is stored in one of the plurality of configuration memory circuits by controlling the respective second switching circuit and the selection device, preferably.

The plurality of first switching circuits can be coupled to the output data of the plurality of configuration memory circuits via inverter circuits, preferably.

The programmable logic device, further includes: an inverter coupled to the selection device and the output data of the plurality of configuration memory circuits; and a transistor having a first electrode connected to a power supply voltage and a second electrode connected to an input of the inverter, wherein a gate electrode of the transistor is connected to an output of the inverter, preferably.

One of the plurality of configuration memory circuits includes: a first PMOS transistor; an inverter circuit having an input port and an output port; a second PMOS transistor; a set line; and an NMOS transistor; wherein a source electrode of the first PMOS transistor is connected to a power-supply voltage, a drain electrode of the first PMOS transistor is connected to the output port of the inverter circuit, the output port of the inverter circuit is connected to the output port of the one configuration memory circuit, the input port of the inverter circuit is connected to the input port of the one configuration memory circuit, a source electrode of the second PMOS transistor is connected to the set line, a drain electrode of the second PMOS transistor is connected to the output port of the one configuration memory circuit and a drain electrode of the NMOS transistor, a gate electrode of the second PMOS transistor and a gate electrode of the NMOS transistor are connected to the input port of the one configuration memory circuit, preferably.

A programmable logic device according to another aspect includes a plurality of repeating units, each of which includes interconnecting lines, a logic block comprising logic circuits, and a plurality of configuration memory circuits, wherein one of the plurality of repeating units includes: a first configuration memory circuit, included in the plurality of configuration memory circuits, having an input port and output port; a first delayed-flipflop having a data input port, a clock input port and a data output port; a multiplexer having a first input port, a second input port, an output port and a control port, a data-in line; a first switch circuit having an input port, an output port and a control port; and a second switch circuit having an input port, an output port and a control port; wherein the output port of the first configuration memory circuit is connected to the input port of the first switch circuit, the input port of the first configuration memory circuit is connected to the output port of the second switch circuit, the output port of the first switch circuit is connected to the first input port of the multiplexer, the input port of the second switch circuit is connected to the data-in line, the data-in line is connected to the second input port of the multiplexer, and the output port of the multiplexer is connected to the data input port of the first delayed-flip-flop. Another of the plurality of repeating units includes a second delayed-flip-flop having a data input port, a clock input port and a data output port, and the data output port of the second delayed-flipflop is connected to the data-in line, preferably.

One of the plurality of repeating units further includes: a second configuration memory circuit, included in the plurality of configuration memory circuits, having an input port and output port, a third switch circuit having an input port, an output port and a control port; and a fourth switch circuit having an input port, an output port and a control port; wherein the output port of the second configuration memory circuit is connected to the input port of the third switch circuit, the input port of the second configuration memory circuit is connected to the output port of the fourth switch circuit, the output port of the third switch circuit is connected to the first input port of the multiplexer, and the input port of the fourth switch circuit is connected to the data-in line, preferably.

When data stored in the first configuration memory circuit is read out, the first switch circuit is controlled to be conductive according to a first control signal provided at the control port of the first switch circuit, and the multiplexer is controlled to output data provided at the first input port of the multiplexer according to a mux control signal provided at the control port of the multiplexer, preferably.

When data to be stored in the first configuration memory circuit is provided at the data-in line, the second switch circuit is controlled to be conductive according to the first control signal provided at the control port of the first switch circuit, preferably.

The output port of the first configuration memory circuit is connected to the input port of the first switch circuit via an inverter circuit, preferably.

The first configuration memory circuit comprises: a first PMOS transistor; an inverter circuit having an input port and an output port; a second PMOS transistor; a set line; and an NMOS transistor; wherein a source electrode of the first PMOS transistor is connected to a power-supply voltage, a drain electrode of the first PMOS transistor is connected to the output port of the inverter circuit, the output port of the inverter circuit is connected to the input port of the first configuration memory circuit, the input port of the inverter circuit is connected to the output port of the first configuration memory circuit, a source electrode of the second PMOS transistor is connected to the set line, a drain electrode of the second PMOS transistor is connected to the output port of the configuration memory circuit and a drain electrode of the NMOS transistor, a gate electrode of the second PMOS transistor and a gate electrode of the NMOS transistor are connected to the input port of the first configuration memory circuit, preferably.

The first configuration memory circuit further comprises: a third PMOS transistor having a source electrode connected to the power supply voltage, a drain electrode connected to the output of the inverter and a gate electrode connected to the set line, preferably.

By the above-stated structure PLDs comprising compact latch cells can be tested.

### BRIEF DESCRIPTION OF DRAWINGS

FIG. 1 is a diagram of simplified PLD architecture of embodiment 1.

FIG. 2 is a simplified illustration of a tile.

FIG. 3 is simplified circuit diagram of a part of an exemplary test system included in a PLD of the embodiment 1.

FIG. 4 is an exemplary timing chart of the procedure to write data in latch circuits.

FIG. 5 is an exemplary timing chart of the procedure to read data from the latch circuits.

FIG. 6 is simplified circuit diagram of a part of an exemplary test system included in a PLD of the modification example 1 of embodiment 1.

FIG. 7 is a circuit diagram of exemplary latch circuit.

FIG. 8 is a circuit diagram of exemplary latch circuit.

### DESCRIPTION OF EMBODIMENTS

### Embodiment 1

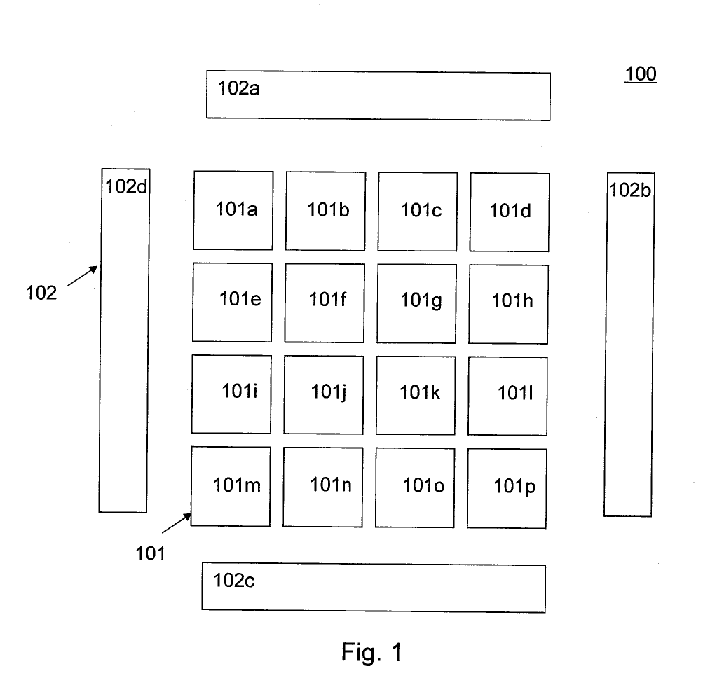

FIG. 1 illustrates simplified PLD architecture 100 of embodiment 1 in plain view. The PLD 100 includes an array of tiles 101a-101p, programmable input/output (I/O) blocks 102a-102d. Some of the tiles 101a-101p and I/O blocks 102a-102d are connected by a number of connecting lines (not shown in the FIG. 1). Clock signals are distributed by, for example, clock trees such as the balanced tree (e.g. the H clock tree).

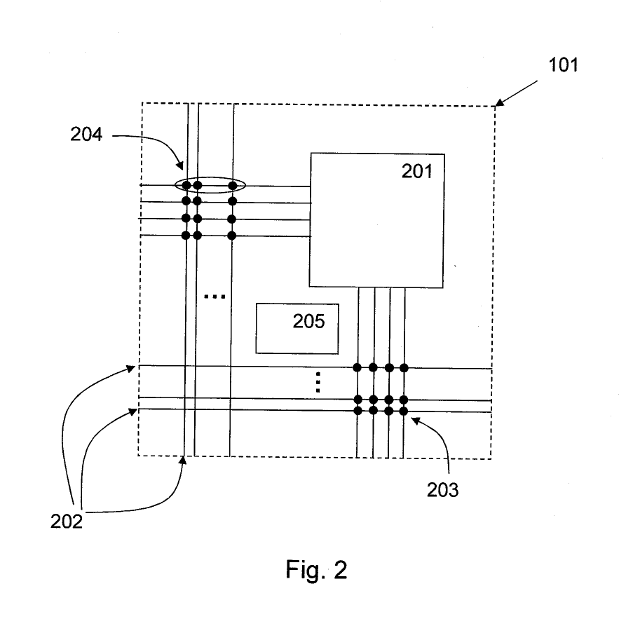

FIG. 2 shows simplified illustration of a tile 101, which is one of the tiles 101a-101p. The tiles 101a-101p have similar structure. In other words, the tile 101 is a repeating unit of the PLD 100. The tile 101 includes a logic block 201, a number of interconnecting lines 202 and a configuration memory block 205. The logic block 201 includes logic circuits and at least one D-FF for holding data. The D-FF can be a part of a scan chain and the D-FF can be tested by conventional scan test. The interconnecting lines are interconnected by programmable interconnect points 203 (PIPs, shown as small dots in FIG. 2). PIPs are often coupled into groups (e.g. group 204) that implement multiplexer circuits selecting one of several interconnecting lines to provide a signal to a destination interconnecting line or the logic block 201. The PIPs 203 are controlled by control signals based on the configuration data stored in the configuration memory block 205. The configuration memory block 205 comprises a plurality of latch circuits.

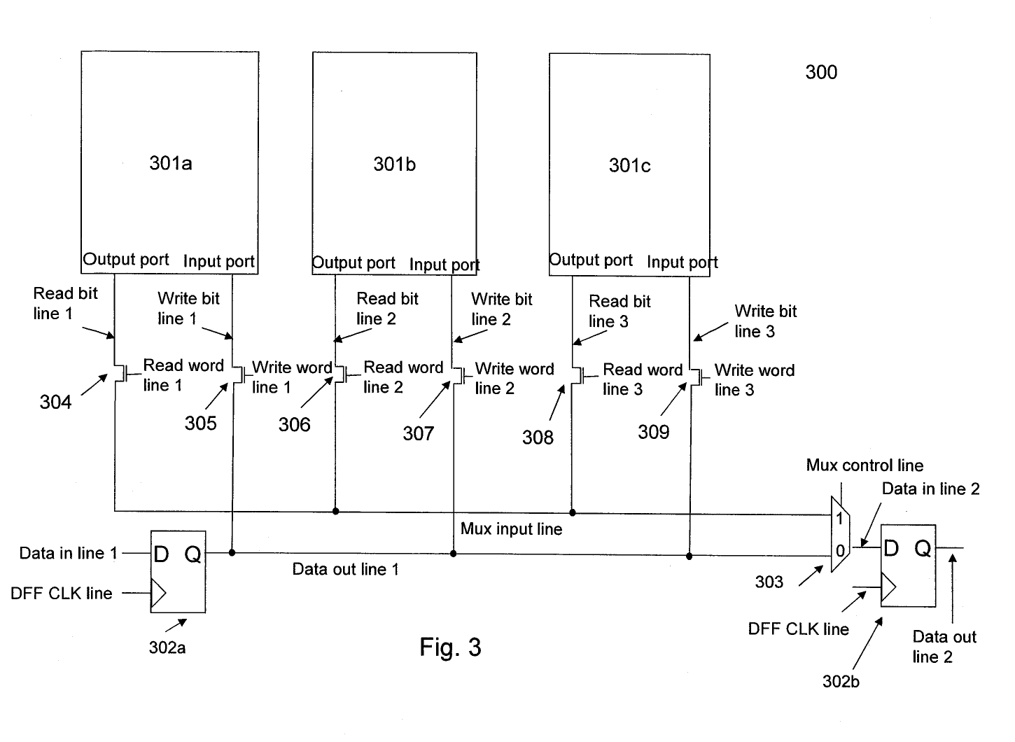

FIG. 3 shows a simplified circuit diagram of a part of an exemplary test system 300 included in the PLD 100 of the embodiment 1. A whole test system of the embodiment 1 includes a scan chain of m D-FFs. FIG. 3 shows 2 D-FFs of the m D-FFs. With the semiconductor integrated circuit of embodiment 1, the automatic test pattern generator (ATPG) can generate test patterns which include the latch circuits included in the configuration memory block 205, and the latch circuits can be tested by using the scan test method. The latch circuits behave like a part of a scan chain.

The part of test system 300 comprises n latch circuits, for example a latch circuit 301a, a latch circuit 301b, and a latch circuit 301c. Each of the n latch circuits has an input port and an output port. Each of the n latch circuits can be written data in from the input port and can be read data out from the output port. The output port of each of the n latch circuits is connected to a read bit line to read data out and the input port of each of the n latch circuits is connected to a write bit line to write data in. Test system 300 further comprises a D-FF 302a and a D-FF 302b which can work as a part of a scan chain. A data in line 1 is connected to a D port of the D-FF 302a. A D-FF CLK line which provides the D-FFs 302a, 302b with a D-FF clock signal, which can be input both from outside of the PLD and from inside of the PLD, is connected to a clock port of the D-FF 302a and a clock port of the D-FF 302b. A data out line 1 for providing a shift chain segment input is connected to a Q port of the D-FF 302a and also connected to an input port of a multiplexer 303. A mux input line is connected to another input port of the multiplexer 303. A mux control line is connected to a control port of the multiplexer 303. N read bit lines are respectively connected to a drain electrode of an NMOS transistor. N write bit lines are respectively connected to a drain electrode of an NMOS transistor. A read bit line 1 is connected to a drain electrode of an NMOS transistor 304 and an output port of the latch circuit 301a. A gate electrode of the NMOS transistor 304 is connected to a read word line 1 and a source electrode of the NMOS transistor 304 is connected to the mux input line. A write bit line 1 is connected to a drain electrode of an NMOS transistor 305 and an input port of the latch circuit 301a. A gate electrode of the NMOS transistor 305 is connected to a write word line 1 and a source electrode of the NMOS transistor 305 is connected to the data out line 1. A read bit line 2 is connected to a drain electrode of an NMOS transistor 306 and an output port of the latch circuit 301b. A gate electrode of the NMOS transistor 306 is connected to a read word line 2 and a source electrode of the NMOS transistor 306 is connected to the mux input line. A write bit line 2 is connected to a drain electrode of an NMOS transistor 307 and an input port of the latch circuit 301b. A gate electrode of the NMOS transistor 307 is connected to a write word line 2 and a source electrode of the NMOS transistor 307 is connected to the data out line 1. A read bit line 3 is connected to a drain electrode of an NMOS transistor 308 and an output port of the latch circuit 301c. A gate electrode of the NMOS transistor 308 is connected to a read word line 3 and a source electrode of the NMOS transistor 308 is connected to the mux input line. A write bit line 3 is connected to a drain electrode of an NMOS transistor 309 and an input port of the latch circuit 301c. A gate electrode of the NMOS transistor 309 is connected to a write word line 3 and a source electrode of the NMOS transistor 309 is connected to the data out line 1. The output port of the multiplexer 303 is connected to a data in line 2. The data in line 2 is connected to a D port of a D-FF 302b. A data out line 2 for outputting a shift chain segment output is connected to a Q port of the D-FF 302b. In the embodiment 1, the n latch circuits, the multiplexer 303 and the D-FF 302b are included in one tile 101, and the D-FF 302a is included in another tile 101 next to the one tile of the D-FF 302b. For example, the n latch circuits, the multiplexer 303 and the D-FF 302b are included in the tile 101g, and the D-FF 302a is included in the tile 101f. However, for example, the structure that the D-FF 302a and the n latch circuits are included in tile 101f, and the multiplexer 303 and the D-FF 302b are included in 101g, is also possible.

A data is input to the D-FF 302a from the data in line 1. The D-FF 302a outputs a data, which corresponds to the input data from the data in line 1 at the time of rising edge of the D-FF clock signal, to the data out line 1. The mux select one of the mux input line and data out line 1 to electrically connect to the data in line 2 according to the signal of the mux control line. When the signal of the mux control line is logic 1, the mux input line is electrically connected to the data in line 2 and a signal of the mux input line is sent to the data in line 2. When the signal of the mux control line is logic 0, the data out line 1 is electrically connected to the data in line 2 and a signal of the data out line 1 is sent to the data in line 2. The D-FF 302b outputs a data, which corresponds to the input data by the data in line 2 at the time of rising edge of the D-FF clock signal, to the data out line 2.

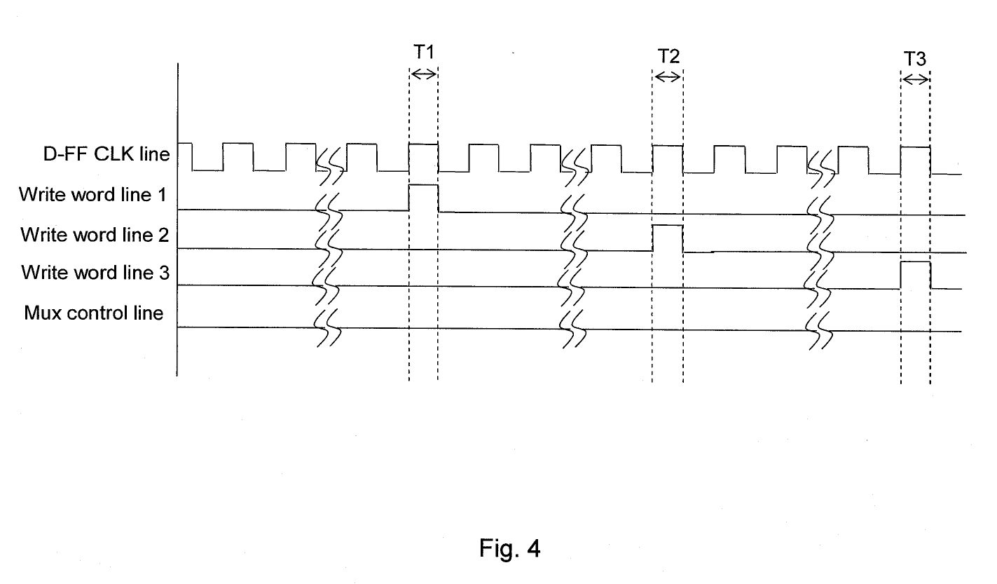

Test of the n latch circuits comprises a procedure to write data in n latch circuits, and a procedure to read data from the n latch circuits. By investigating the data read out from the n latch circuits, faults of the n latch circuits can be detected. An example of the procedure to write data in the latch circuits 301a, 301b and 301c is shown in FIG. 4. Each line shows a voltage of corresponding line. Low voltage is representing logic 0, and high voltage is representing logic 1.

Before time T1 of the FIG. 4, before writing data in the latch circuit 301a, a voltage of the write word line 1, the write word line 2, the write word line 3 and the mux control line are low. A voltage of the read word line 1, the read word line 2, and the read word line 3 is low during the procedure to write data in n latch circuits (not shown in the FIG. 4). Before writing data in the latch circuit 301a, at least m clock pulses are input to the D-FF CLK line to fill the scan chain with input data to latch circuits included in configuration memories.

At time T1 of the FIG. 4, a data of the data out line 1 at T1 is written in the latch circuit 301a. At time of rising edge of the D-FF clock signal, a data of the data in line 1 is output from the D-FF 302a to the data out line 1. A voltage of the write word line 1 is high and the NMOS transistor 305 is turned on. The data of the data out line 1 at the time T1 is input to the latch circuit 301a via the write bit line 1. The data of the data out line 1 at the time T1 is stored in the latch circuit 301a. The voltage of the write word line 2, the write word line 3 and the mux control line is low.

After the time T1 and before time T2 of the FIG. 4, after writing data in the latch circuit 301a and before writing data in the latch circuit 301b, at least m clock pulses are input to the D-FF CLK line to fill the scan chain with input data to latch circuits included in configuration memories. A voltage of the write word line 1, the write word line 2, the write word line 3 and the mux control line are low.

At time T2 of the FIG. 4, a data of the data out line 1 at T2 is written in the latch circuit 301b. At time of rising edge of the D-FF clock signal, a data of the data in line 1 is output from the D-FF 302a to the data out line 1. A voltage of the write word line 2 is high and the NMOS transistor 307 is turned on. The data of the data out line 1 at the time T2 is input to the latch circuit 301b via the write bit line 2. The data of the data out line 1 at the time T2 is stored in the latch circuit 301b. The voltage of the write word line 1, the write word line 3 and the mux control line is low.

After the time T2 and before time T3 of the FIG. 4, after writing data in the latch circuit 301b and before writing data in the latch circuit 301c, at least m clock pulses are input to the D-FF CLK line to fill the scan chain with input data to latch circuits included in configuration memories. A voltage of the write word line 1, the write word line 2, the write word line 3 and the mux control line are low.

At time T3 of the FIG. 4, a data of the data out line 1 at T3 is written in the latch circuit 301c. At time of rising edge of the D-FF clock signal, a data of the data in line 1 is output from the D-FF 302a to the data out line 1. A voltage of the write word line 3 is high and the NMOS transistor 309 is turned on. The data of the data out line 1 at the time T3 is input to the latch circuit 301c via the write bit line 3. The data of the data out line 1 at the time T3 is stored in the latch circuit 301c. The voltage of the write word line 1, the write word line 2 and the mux control line is low. This procedure continues until writing data in all of the latch circuits included in the configuration memories of PLD 100.

In the FIG. 4, the voltage of the mux control line is always low, but the voltage of the mux control line can be high during the procedure of writing data in the latch circuits.

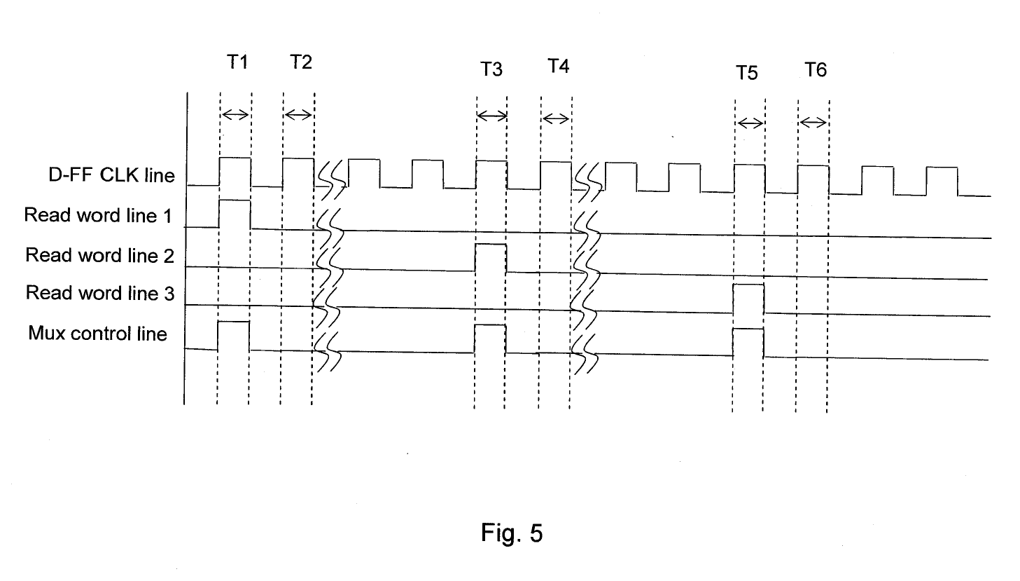

An example of the procedure to read data from the latch circuits 301a, 301b and 301c is shown in FIG. 5. The procedure to read data from the latch circuits follow on directly from the procedure to write data in the latch circuits. Each line shows a voltage of corresponding line.

At time T1 of the FIG. 5, the data stored in the latch circuit 301a is input to the D-FF 302b. A voltage of the read word line 1 is high and the NMOS transistor 304 is turned on. The data stored in the latch circuit 301a is input to the mux input line via the read bit line 1. The voltage of the mux control line is high and the mux input line is electrically connected to the data in line 2. The data stored in the latch circuit 301a is input to the data in line 2. A voltage of the read word line 2 and the read word line 3 is low. The D-FF clock signal is high.

At time T2 of the FIG. 5, the D-FF clock signal is high. The D-FF 302b outputs a data, which corresponds to the input data from the data in line 2 at the time of rising edge of the D-FF clock signal at the time T2, to the data out line 2. At the time T2, the input data from the data in line 2 is the data stored in the latch circuit 301a. Therefore, the D-FF 302b outputs the data stored in the latch circuit 301a. The voltage of the read word line 1, the read word line 2, the read word line 3 and the mux control line is low.

After the time T1 and before time T3 of the FIG. 5, after reading data from the latch circuit 301a and before reading data from the latch circuit 301b, at least m clock pulses are input to the D-FF CLK line to read out all data stored in the scan chain. A voltage of the write word line 1, the write word line 2, the write word line 3 and the mux control line are low.

At time T3 of the FIG. 5, the data stored in the latch circuit 301b is input to the D-FF 302b. A voltage of the read word line 2 is high and the NMOS transistor 306 is turned on. The data stored in the latch circuit 301b is input to the mux input line via the read bit line 2. The voltage of the mux control line is high and the mux input line is electrically connected to the data in line 2. The data stored in the latch circuit 301b is input to the data in line 2. A voltage of the read word line 1 and the read word line 3 is low. The D-FF clock signal is high.

At time T4 of the FIG. 5, the D-FF clock signal is high. The D-FF 302b outputs a data, which corresponds to the input data from the data in line 2 at the time of rising edge of the D-FF clock signal at the time T4, to the data out line 2. At the time T4, the input data from the data in line 2 is the data stored in the latch circuit 301b. Therefore, the D-FF 302b outputs the data stored in the latch circuit 301b. The voltage of the read word line 1, the read word line 2, the read word line 3 and the mux control line is low.

After the time T3 and before time T5 of the FIG. 5, after reading data from the latch circuit 301b and before reading data from the latch circuit 301c, at least m clock pulses are input to the D-FF CLK line to read out all data stored in the scan chain. A voltage of the write word line 1, the write word line 2, the write word line 3 and the mux control line are low.

At time T5 of the FIG. 5, the data stored in the latch circuit 301c is input to the D-FF 302b. A voltage of the read word line 3 is high and the NMOS transistor 308 is turned on. The data stored in the latch circuit 301c is input to the mux input line via the read bit line 3. The voltage of the mux control line is high and the mux input line is electrically connected to the data in line 2. The data stored in the latch circuit 301c is input to the data in line 2. A voltage of the read word line 1 and the read word line 2 is low. The D-FF clock signal is high.

At time T6 of the FIG. 5, the D-FF clock signal is high. The D-FF 302b outputs a data, which corresponds to the input data from the data in line 2 at the time of rising edge of the D-FF clock signal at the time T6, to the data out line 2. At the time T6, the input data from the data in line 2 is the data stored in the latch circuit 301c. Therefore, the D-FF 302b outputs the data stored in the latch circuit 301c. The voltage of the read word line 1, the read word line 2, the read word line 3 and the mux control line is low. After the time T5, after reading data from the latch circuit 301c, at least m clock pulses are input to the D-FF CLK line to read out all data stored in the scan chain. A voltage of the write word line 1, the write word line 2, the write word line 3 and the mux control line are low.

The procedure to read data from the latch circuits will continue until reading out data from all of the latch circuits included in configuration memories of the PLD 100.

As described above, with the PLD of embodiment 1, latch circuits can be tested by scan test.

### Modification Example 1 of Embodiment 1

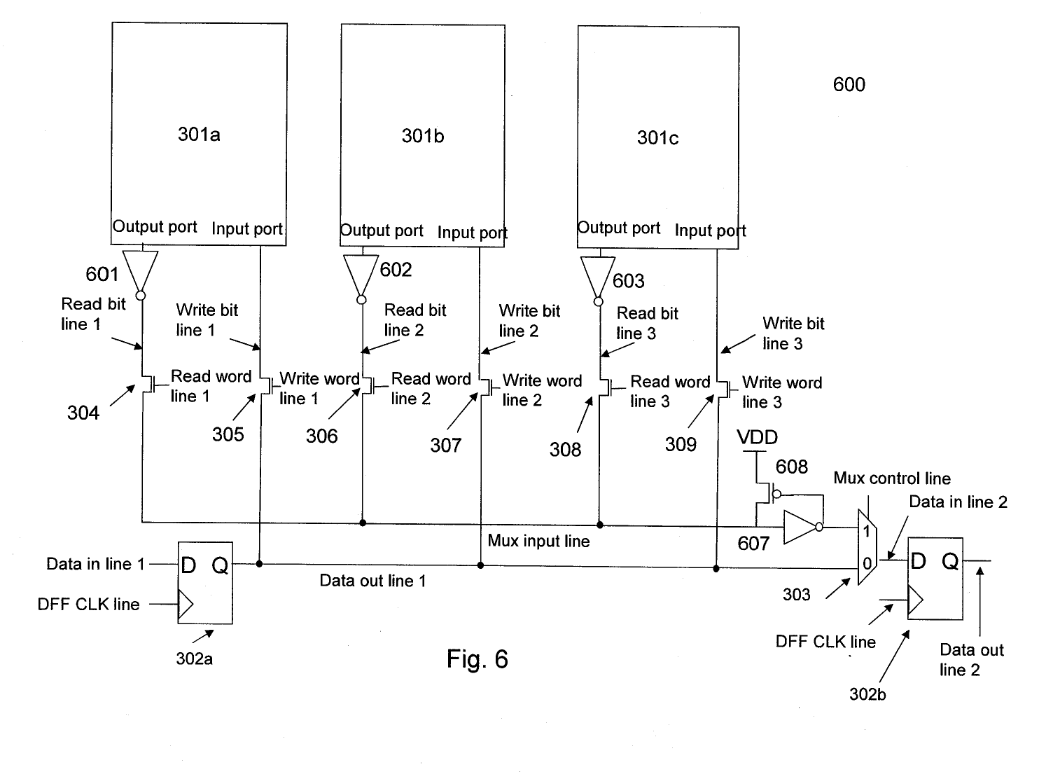

Instead of the part of test system 300 as shown in the FIG. 3, a part of a test system 600 as shown in FIG. 6 can also be applied to the procedures shown in the FIG. 4 and FIG. 5. The difference between the part of the test system shown in the FIG. 3 and the part of the test system shown in the FIG. 6 is that the part of the test system 600 further comprises an inverter 601, an inverter 602 and an inverter 603. An input of the inverter 601 is connected to the output port of the latch circuit 301a, an input of the inverter 602 is connected to the output port of the latch circuit 301b, and an input of the inverter 603 is connected to the output port of the latch circuit 301c. An output of the inverter 601 is connected to the drain electrode of the NMOS transistor 304, an output of the inverter 602 is connected to the drain electrode of the NMOS transistor 306, an output of the inverter 603 is connected to the drain electrode of the NMOS transistor 308.

These additional inverters 601, 602 and 603 prevent the noise which comes from the read bit line 1, read bit line 2 and read bit line 3, respectively, of flipping the data stored in the latch circuit 301a, 301b, and 301c.

Another difference between the semiconductor integrated circuit shown in the FIG. 6 and the semiconductor integrated circuit shown in the FIG. 3 is that the semiconductor integrated circuit 600 further comprises an inverter 607 and a PMOS transistor 608. A source electrode of the PMOS transistor 608 is connected to a power-supply voltage VDD. A drain electrode of the PMOS transistor 608 is connected to an input of the inverter 607. A gate electrode of the PMOS transistor 608 is connected to an output of the inverter 607. The output of the inverter 607 is connected to the input of the multiplexer 303. The input of the inverter 607 is connected to the mux input line.

The additional inverter 607 and the PMOS transistor 608 keep the voltage of the mux input line proper. When the latch circuit 301a, 301b and 301c store logic 1 and the stored logic 1 is read out via read bit line 1, 2, and 3, voltage propagates to the mux input line is lower than that of the read bit lines 1, 2, and 3 because of the NMOS transistor 304, 306 and 308. However, the inverter 607 inverses the logic 1 to logic 0 and outputs proper voltage.

### Modification Example 2 of Embodiment 1

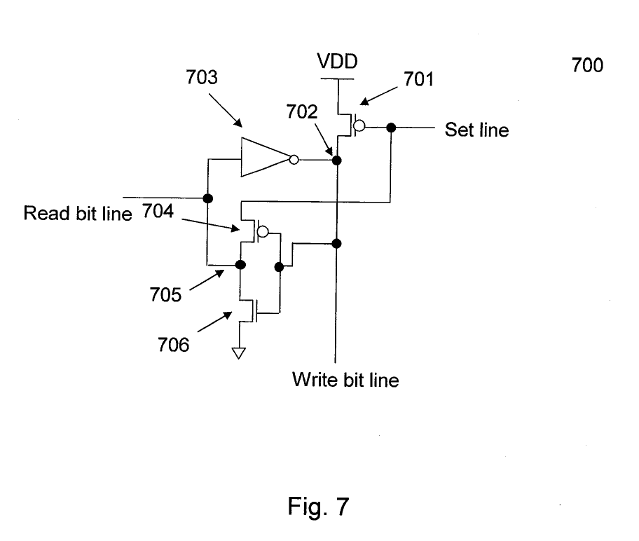

FIG. 7 shows a circuit diagram of exemplary latch circuit 700 which can be used as the n latch circuits.

The latch circuit 700 comprises a set line, a write bit line, a read bit line, a PMOS transistor 701, an inverter 703, a PMOS transistor 704, and a NMOS transistor 706. The latch circuit 700 has a bit line to write data in the latch circuit 700 and a read bit line to read data out from the latch circuit 700. A source electrode of the PMOS transistor 701 is connected to a voltage high which corresponds to logic 1, typically a power-supply voltage VDD. A drain electrode of the PMOS transistor 701 is connected to a node 702, and a gate electrode of the PMOS 701 is connected to the set line. An output of the inverter 703 is connected to the node 702. An input of the inverter 703 is connected to a node 705. A drain electrode of the PMOS transistor 704 is also connected to the node 705, and a source electrode of the PMOS transistor 704 is connected to the set line. A drain electrode of the NMOS 706 is connected to the node 705, and the source electrode of the transistor 706 is connected to a voltage low which corresponds to logic 0, typically electrical ground. A gate electrode of the PMOS transistor 704 and a gate electrode of the NMOS transistor 706 are connected to the node 702. The node 702 is connected to the write bit line.

The bit line is used to write data to the latch circuit 700. Data is stored at the node 702 in the latch circuit 700. The set line is used to preset the voltage of node 702 to high before writing data into the latch circuit 700, by turning on the PMOS transistor 701. In order to turning on the PMOS transistor 701, the voltage of the set line is driven to the voltage low before writing data in the latch circuit 700. Before writing data into the latch circuit 700, logic 1 is stored in the latch circuit 700, at the node 702. Therefore, it is easier to write logic 1 to the latch circuit 700. Moreover, we can realize this memory with only 5 transistors. This is effective to conserve area of the chip on which semiconductor integrated circuit including the latch circuit 700 is fabricated.

The source electrode of the PMOS transistor 704 is connected to the set line to make the latch circuit 700 stable. If the source electrode of the PMOS transistor 704 is connected to a power-supply voltage VDD and logic 0 is stored in the latch circuit 700 before the preset, when the voltage of the set line is driven to the voltage low, the pull-up of the PMOS transistor 701 would have to fight the pull down of the inverter 703. In this case, the pull-up of the PMOS transistor 701 may not always win. Therefore, the node 702 cannot always store logic 1 before writing in the latch circuit 700, this means that the preset cannot always succeed. This makes the function of the latch circuits unstable. But as shown in FIG. 7, the source electrode of the PMOS transistor 704 is connected to the set line. Even if logic 0 is stored in the latch circuit 700 before the preset, when the voltage of the set line is driven to the voltage low, the voltage of the node 705 is also driven to the voltage low because the PMOS transistor is conductive. The voltage of the node 705 is the voltage low which is representing logic 0, so the output signal of the inverter is logic 1. Therefore, the voltage of the node 702 is successfully driven to the voltage high, which is representing logic 1. The preset can be carried out successfully. This makes the latch circuit 700 stable.

Moreover, if the source electrode of the PMOS transistor 704 is connected to a power-supply voltage VDD and logic 0 is stored in the latch circuit 700 before the preset, it takes more time for the latch circuit 700 to store logic 0 successfully than for the latch circuit 700 with the source electrode of the PMOS transistor 704 being connected to the set line. If the source electrode of the PMOS transistor 704 is connected to a power-supply voltage VDD and logic 0 is stored in the latch circuit 700 before the preset, when the voltage of the set line is driven to the voltage low, the voltage of the node 702 become high if the pull-up of the PMOS transistor 701 wins the fight with pull-down of the inverter 703. Then the voltage of the node 705 becomes low because the NMOS transistor 706 is turned on. This means that the logic 1 is stored in the latch circuit 700. The voltage of the node 705 is changed after the pull-up of the 702. On the contrary, when the source electrode of the PMOS transistor 704 is connected to the set line as shown in the FIG. 7, the voltage of the node 705 is changed almost at the same time as the pull-up of the voltage of the node 702, because the PMOS transistor 704 is conductive and the node 705 is electrically connected to the set line. Therefore, the latch circuit 700 as shown in the FIG. 7 can store data rapidly.

When the latch cell 700 is applied to the test system shown in FIG. 3, before the procedure to write data in n latch circuits, the voltage of the set line is driven to high to preset the latch circuits.

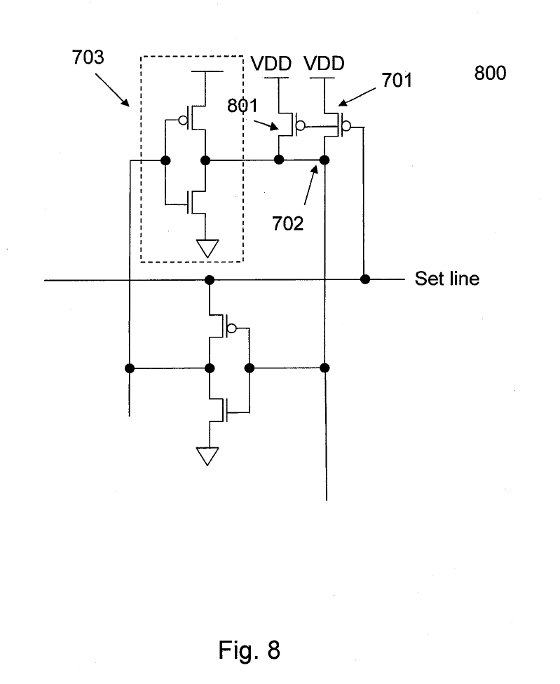

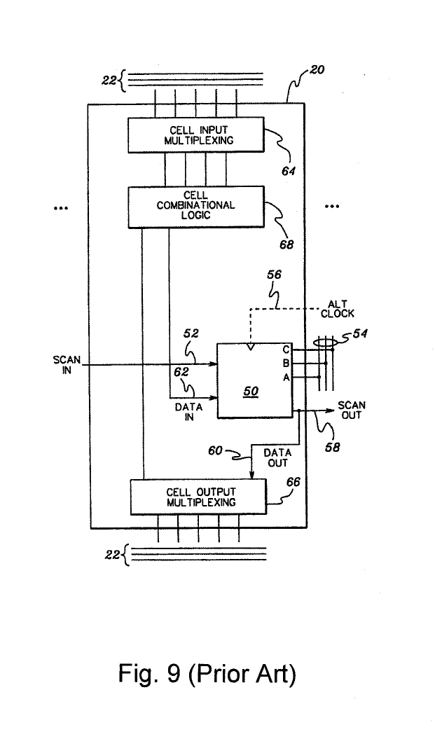

As the latch circuits 301, 301b and 301c, instead of the structure shown in the FIG. 7, a latch circuits shown in FIG. 8 can be applied. The difference between the latch circuit 700 and a latch circuit 800 is that the latch circuit 800 further comprises a PMOS transistor 801. A source electrode of the PMOS transistor 801 is connected to the power-supply voltage VDD. A drain electrode of the PMOS transistor 801 is connected to the node 702 and to the output of the inverter 703. A gate electrode of the PMOS 801 is connected to the set line. The additional PMOS transistor 801 improves the preset function.

Generally, the present disclosure concerns a programmable logic device 100 comprising a plurality of repeating units 101a-101p, each of which includes interconnecting lines 202, a logic block 201 comprising logic circuits, and a configuration memory block 205 including a plurality of configuration memory circuits 301a-301c, One of the plurality of repeating units includes a selection device such as multiplexer 303 coupled to output data of the plurality of configuration memory circuits 301a-301c, and a shift chain segment input (Data out line 1); and a flip flop 302b receiving output of the selection device 303 to output a shift chain segment output.

The plurality of configuration memory circuits can be latch circuits. Further, another of the plurality of repeating units includes another flip flop 302a for providing the shift chain segment input.

The one of the plurality of repeating units can further include: a plurality of first switching circuits 304, 306, 308 coupled to the output data of the plurality of configuration memory circuits 301a-301c respectively and the selection device 303; and a plurality of second switching circuits 305, 307, 309 coupled to input data of the plurality of configuration memory circuits 301a-301c respectively and the shift chain segment input, Data can be read from one of the plurality of configuration memory circuits 301a-301c by controlling the respective first switching circuit and the selection device, Data can be stored in one of the plurality of configuration memory circuits 301a-301c by controlling the respective second switching circuit and the selection device.

The plurality of first switching circuits can be coupled to the output data of the plurality of configuration memory circuits 301a-301c via inverter circuits. The programmable logic device can further include: an inverter 607 coupled to the selection device 303 and the output data of the plurality of configuration memory circuits 301a-301c; and a transistor 608 having a first electrode connected to a power supply voltage and a second electrode connected to an input of the inverter 607. A gate electrode of the transistor 608 can be connected to an output of the inverter 607. At least one of the plurality of configuration memory circuits can include: a first PMOS transistor; an inverter circuit having an input port and an output port; a second PMOS transistor; a set line; and an NMOS transistor. The source electrode of the first PMOS transistor is connected to a power-supply voltage and the drain electrode of the first PMOS transistor is connected to the output port of the inverter circuit. The output port of the inverter circuit is connected to the output port of the one configuration memory circuit, and the input port of the inverter circuit is connected to the input port of the one configuration memory circuit, The source electrode of the second PMOS transistor is connected to the set line, the drain electrode of the second PMOS transistor is connected to the output port of the one configuration memory circuit and a drain electrode of the NMOS transistor, and the gate electrode of the second PMOS transistor and gate electrode of the NMOS transistor are connected to the input port of the one configuration memory circuit.

Although the invention has been described in conjunction with particular embodiments, it will be appreciated that various modifications and alternations may be made by those skilled in the art without departing from the spirit and scope of the invention.

### INDUSTRIAL APPLICABILITY

This invention can provide a more integrated circuit.

1. A programmable logic device comprising a plurality of repeating units, each of which includes interconnecting lines, a logic block comprising logic circuits, and a configuration memory block including a plurality of configuration memory circuits, wherein one of the plurality of repeating units includes:
a selection device coupled to output data of the plurality of configuration memory circuits and a shift chain segment input; and
a flip flop receiving output of the selection device to output a shift chain segment output.

2. The programmable logic device of claim 1, wherein the plurality of configuration memory circuits are latch circuits.

3. The programmable logic device of claim 1, wherein another of the plurality of repeating units includes another flip flop for providing the shift chain segment input.

4. The programmable logic device of claim 1, wherein the one of the plurality of repeating units further includes:
a plurality of first switching circuits coupled to the output data of the plurality of configuration memory circuits respectively and the selection device; and
a plurality of second switching circuits coupled to input data of the plurality of configuration memory circuits respectively and the shift chain segment input,
wherein data is read from one of the plurality of configuration memory circuits by controlling the respective first switching circuit and the selection device,
wherein data is stored in one of the plurality of configuration memory circuits by controlling the respective second switching circuit and the selection device.

5. The programmable logic device of claim 4, wherein the plurality of first switching circuits are coupled to the output data of the plurality of configuration memory circuits via inverter circuits.

6. The programmable logic device of claim 4, further comprising:
an inverter coupled to the selection device and the output data of the plurality of configuration memory circuits; and
a transistor having a first electrode connected to a power supply voltage and a second electrode connected to an input of the inverter,
wherein a gate electrode of the transistor is connected to an output of the inverter.

7. The programmable logic device of claim 1, wherein one of the plurality of configuration memory circuits includes:
a first PMOS transistor;
an inverter circuit having an input port and an output port;
a second PMOS transistor;
a set line; and
an NMOS transistor; wherein
a source electrode of the first PMOS transistor is connected to a power-supply voltage,
a drain electrode of the first PMOS transistor is connected to the output port of the inverter circuit,
the output port of the inverter circuit is connected to the output port of the one configuration memory circuit,
the input port of the inverter circuit is connected to the input port of the one configuration memory circuit,
a source electrode of the second PMOS transistor is connected to the set line,
a drain electrode of the second PMOS transistor is connected to the output port of the one configuration memory circuit and a drain electrode of the NMOS transistor,
a gate electrode of the second PMOS transistor and a gate electrode of the NMOS transistor are connected to the input port of the one configuration memory circuit.

8. A programmable logic device comprising a plurality of repeating units, each of which includes interconnecting lines, a logic block comprising logic circuits, and a plurality of configuration memory circuits, wherein one of the plurality of repeating units includes:
a first configuration memory circuit, included in the plurality of configuration memory circuits, having an input port and output port;
a first delayed-flipflop having a data input port, a clock input port and a data output port;
a multiplexer having a first input port, a second input port, an output port and a control port,
a data-in line;
a first switch circuit having an input port, an output port and a control port; and
a second switch circuit having an input port, an output port and a control port; wherein
the output port of the first configuration memory circuit is connected to the input port of the first switch circuit,
the input port of the first configuration memory circuit is connected to the output port of the second switch circuit,
the output port of the first switch circuit is connected to the first input port of the multiplexer,
the input port of the second switch circuit is connected to the data-in line, the data-in line is connected to the second input port of the multiplexer, and the output port of the multiplexer is connected to the data input port of the first delayed-flip-flop.

9. The programmable logic device of claim 8, wherein
another of the plurality of repeating units includes a second delayed-flip-flop having a data input port, a clock input port and a data output port, and
the data output port of the second delayed-flipflop is connected to the data-in line.

10. The programmable logic device of claim 9, wherein the one of the plurality of repeating units further includes:
a second configuration memory circuit, included in the plurality of configuration memory circuits, having an input port and output port,
a third switch circuit having an input port, an output port and a control port; and
a fourth switch circuit having an input port, an output port and a control port; wherein
the output port of the second configuration memory circuit is connected to the input port of the third switch circuit,
the input port of the second configuration memory circuit is connected to the output port of the fourth switch circuit,
the output port of the third switch circuit is connected to the first input port of the multiplexer, and
the input port of the fourth switch circuit is connected to the data-in line.

11. The programmable logic device of claim 9, wherein
when data stored in the first configuration memory circuit is read out,
the first switch circuit is controlled to be conductive according to a first control signal provided at the control port of the first switch circuit, and
the multiplexer is controlled to output data provided at the first input port of the multiplexer according to a mux control signal provided at the control port of the multiplexer.

12. The programmable logic device of claim 11, wherein
when data to be stored in the first configuration memory circuit is provided at the data-in line,
the second switch circuit is controlled to be conductive according to the first control signal provided at the control port of the first switch circuit.

13. The programmable logic device of claim 9, wherein
the output port of the first configuration memory circuit is connected to the input port of the first switch circuit via an inverter circuit.

14. The programmable logic device of claim 9, wherein the first configuration memory circuit comprises:
a first PMOS transistor;
an inverter circuit having an input port and an output port;
a second PMOS transistor;
a set line; and
an NMOS transistor; wherein
a source electrode of the first PMOS transistor is connected to a power-supply voltage,
a drain electrode of the first PMOS transistor is connected to the output port of the inverter circuit,
the output port of the inverter circuit is connected to the input port of the first configuration memory circuit,
the input port of the inverter circuit is connected to the output port of the first configuration memory circuit,
a source electrode of the second PMOS transistor is connected to the set line,
a drain electrode of the second PMOS transistor is connected to the output port of the configuration memory circuit and a drain electrode of the NMOS transistor,
a gate electrode of the second PMOS transistor and a gate electrode of the NMOS transistor are connected to the input port of the first configuration memory circuit.

15. The programmable logic device of claim 14, wherein the first configuration memory circuit further comprises:
a third PMOS transistor having a source electrode connected to the power supply voltage, a drain electrode connected to the output of the inverter (703) and a gate electrode connected to the set line.
an inverter coupled to the selection device and the output data of the plurality of configuration memory circuits; and
a transistor having a first electrode connected to a power supply voltage and a second electrode connected to an input of the inverter,
wherein a gate electrode of the transistor is connected to an output of the inverter, preferably.
